(19) United States
(12) Patent Application Publication
(10) Pub. No.: US 2024/0213959 A1
(43) Pub. Date: Jun. 27, 2024

(54) SYSTEMS AND METHODS FOR NOISE DETECTION AND RESPONSE

(71) Applicant: Rivian IP Holdings, LLC, Plymouth, MI (US)

(72) Inventors: Yanjun Shi, Torrance, CA (US); Zahra Mohajerani, Los Angeles, CA (US)

(21) Appl. No.: 18/085,790

(22) Filed: Dec. 21, 2022

(51) Int. Cl. H03H 17/02

(52) U.S. Cl. CPC H03H 17/0219; H02P 23/14

(57) ABSTRACT

Systems and methods are provided for detecting noise in one or more of samples of a first signal that corresponds to a phase current of a multiphase system, determining to apply a digital noise filter based on the noise, and applying a digital noise filter. Applying the digital noise filter may include generating a reconstructed signal based on two other signals corresponding to respective phase currents of the multiphase system, and outputting the reconstructed signal to replace the one or more samples.

### INTRODUCTION

The present disclosure is directed to noise detection and response and, more particularly, to switchable noise filters using reconstructed signals.

### SUMMARY

In some embodiments, the present disclosure is directed to systems and methods for applying a switchable noise filter. In some embodiments, the present disclosure is directed to a method including detecting noise in one or more of samples of a first signal that corresponds to a phase current of a multiphase system, determining, based on the noise, to apply a digital noise filter, and applying the digital noise filter. Applying the digital noise filter may include generating a reconstructed signal based on two other signals corresponding to respective phase currents of the multiphase system, and outputting the reconstructed signal to replace the one or more samples. In some embodiments, generating the reconstructed signal includes combining the two other signals to generate a combined signal.

In some embodiments, the first signal, a second signal, and a third signal correspond to respective phase currents of a three-phase system. In some such embodiments, generating the reconstructed signal includes summing the second signal and the third signal to generate a reference signal, and changing the sign of the reference signal to result in the reconstructed signal.

In some embodiments, detecting the noise includes identifying an oldest sample in stored sorted data comprising N samples of the first signal, replacing the oldest sample with a new sample, reordering the sorted data to form updated sorted data, and identifying a median value among the updated sorted data. In some embodiments, detecting the noise includes determining phase information (e.g., a phase delay), and shifting the median value based on the phase information to lessen a phase delay. For example, the method may include using a phase-locked loop to identify or estimate a phase shift.

In some embodiments, detecting the noise includes determining a mean based on N samples of the first signal, and comparing the one or more samples to the mean. In some embodiments, detecting the noise includes determining a median value based on the first signal, determining an upper band and a lower band based on the median value, and detecting the noise by determining whether the one or more samples are within a band defined by the upper band and the lower band.

In some embodiments, the present disclosure is directed to a system that includes a sensor system configured to generate a first signal that corresponds to a phase current of a multiphase system and control circuitry. In some embodiments, the control circuitry is configured to sample the first signal, detect noise in one or more of samples of a first signal, determine, based on the noise, to apply a digital noise filter, and apply the digital noise filter. In some embodiments, the system is configured to implement the methods described herein. For example, the control circuitry may be configured to apply the digital noise filter by generating a reconstructed signal based on two other signals corresponding to respective phase currents of the multiphase system, and outputting the reconstructed signal to replace the one or more samples.

In some embodiments, the present disclosure is directed to non-transitory computer-readable medium having instructions encoded thereon that when executed by control circuitry cause the control circuitry to implement any of the methods disclosed herein.

### BRIEF DESCRIPTION OF THE DRAWINGS

The present disclosure, in accordance with one or more various embodiments, is described in detail with reference to the following figures. The drawings are provided for purposes of illustration only and merely depict typical or example embodiments. These drawings are provided to facilitate an understanding of the concepts disclosed herein and shall not be considered limiting of the breadth, scope, or applicability of these concepts. It should be noted that for clarity and ease of illustration these drawings are not necessarily made to scale.

FIG. 1 is a block diagram of an illustrative system having signal processing, in accordance with some embodiments of the present disclosure;

FIG. 2 is a flowchart of an illustrative process for applying a digital noise filter, in accordance with some embodiments of the present disclosure;

FIG. 3 is a block diagram of an illustrative power electronics system implementing a signal processing system for signals exhibiting noise, in accordance with some embodiments of the present disclosure;

FIG. 4 is a flowchart of an illustrative process for implementing a switchable noise filter, in accordance with some embodiments of the present disclosure; and

FIG. 5 shows a signal and resulting signals after applying noise mitigation techniques, in accordance with some embodiments of the present disclosure.

### DESCRIPTION

In digital control systems, a sensor and signal conditioning circuit may incur noise such as random noise. For example, in some circumstances, random noise cannot be filtered out by a frequency domain filter without introducing time delay or phase lag. In a further example, in the context of power electronics, a noise filter should remove the noise in real-time (e.g., as the data is collected rather than in post-processing).

In an illustrative example, noise may be filtered using a low pass filter (LPF). However, due to the random nature of the noise, the spectrum of the noise is uncertain, varying, or both. For example, in wide bandgap power electronics applications, the amplitude of the noise can be relatively large or otherwise significant (e.g., as compared to the signal). An LFP with very low bandwidth is needed, which may introduce phase lag that reduces the stability margin of the control system.

In a further illustrative example, a medium filter may be used to remove noise regardless of its amplitude, but may introduce time delay, which may also cause a control system to be unstable. Additional advanced noise filtering methods may be applied in signal processing, image processing, and artificial intelligence. However, some methods are often applied in post-processed (e.g., after collecting the data), and thus do not meet the need of real-time noise filtering (e.g., as may be needed for power electronics systems).

In some embodiments, the present disclosure is directed to a real-time, digital switchable noise filter (SNF). For example, the SNF may be used only when necessary (e.g., as determined by control circuitry of a control system). In some embodiments, the SNF includes a detection component (e.g., a first process) and a signal reconstruction component (e.g., a second process). In some embodiments, the detection component is configured to detect noise features in a signal using any suitable technique (e.g., improved medium filter base methods). When noise is detected, the detection component triggers a switch (e.g., a logic switch) to generate and insert replacement data (e.g., “good data” or otherwise data less impacted by noise) to substitute the original data (e.g., the data exhibiting noise or “bad data”). To illustrate, the signal reconstruction component may be configured to provide the replacement data. In some embodiments, the present disclosure is directed to techniques for detecting noise and generating reconstructed data that may be used in real-time.

Some illustrative benefits of an SNF implementation may include, for example, eliminated time lag or otherwise reduced time delay (e.g., phase lag), real-time noise removal and mitigation (e.g., regardless of amplitude), improved overall robustness of the corresponding system (e.g., a power electronics system), increased survivability under harsh electromagnetic environments, reduced failure rate of the product or system, or a combination thereof. To illustrate, the SNF of the present disclosure may be applied to a direct-current fast charger for an electric vehicle (EV). In a further example, the SNF of the present disclosure may be applied to any suitable power conversion system.

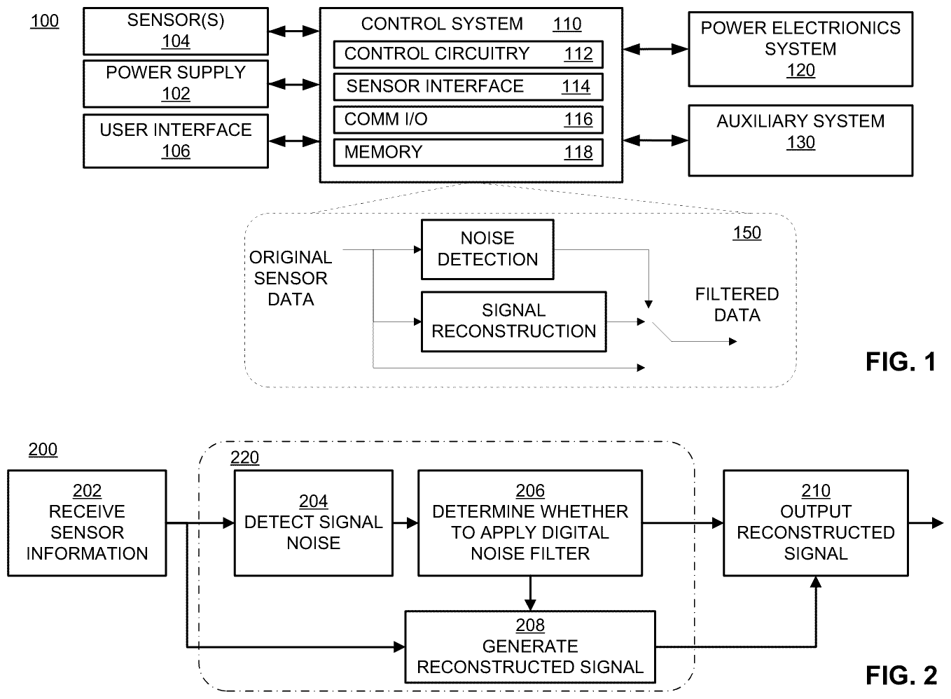

FIG. 1 is a block diagram of illustrative system 100 having signal processing, in accordance with some embodiments of the present disclosure. For example, system 100 may be included as part of, integrated as part of, or otherwise be, an electric vehicle or other suitable system. As illustrated, system 100 includes sensors 104, user interface 106, power supply 102, and control system 110, which includes control circuitry 112, sensor interface 114, communications interface (COMM I/O) 116, and memory 118. Further, system 100 includes power electronics system 120 and auxiliary system 130, as illustrated. Control system 110 may be configured to receive one or more signals from one or more sensors 104, determine suitable signal processing, apply signal processing (e.g., a SNF and/or other suitable technique), generating control signals (e.g., for controlling power electronics system 120 and one or more auxiliary systems 130), storing data, performing any other suitable action, or any combination thereof. It will be understood that system 100 may include more components or less components than illustrated.

Control circuitry 112 may include hardware, software, or both, implemented on one or more modules configured to provide signal processing such as filtering. In some embodiments, control circuitry 112 includes one or more microprocessors, microcontrollers, digital signal processors, programmable logic devices, field-programmable gate arrays (FPGAs), application-specific integrated circuits (ASICs), or any suitable combination thereof. In some embodiments, control circuitry 112 is distributed across more than one processor or processing units. In some embodiments, control circuitry 112 executes instructions stored in memory (e.g., non-transitory computer readable memory such as memory 118) for managing signal processing. In some embodiments, memory 118 is an electronic storage device that is part of control circuitry 112. For example, memory may be configured to store electronic data, computer instructions, applications, firmware, or any other suitable information. In some embodiments, memory 118 includes random-access memory, read-only memory, hard drives, optical drives, solid state devices, or any other suitable memory storage devices, or any combination thereof. For example, memory may be used to launch a start-up routine, signal processing routine, any of the processes of the present disclosure, or any combination thereof.

In some embodiments, control system 110, sensors 104, user interface 106, power electronics system 120, auxiliary system 130, any other suitable system, or any combination thereof are powered by power supply 102. In some embodiments, in the context of an EV and EV charger, power supply 102 includes a car battery (e.g., a 12 V lead acid battery), a battery pack (e.g., a lithium-based battery pack, an EV battery pack), a DC-DC converter, an AC power supply (e.g., generated by suitably inverting a DC power supply), an AC grid, any other power supply, any corresponding components (e.g., terminals, switches, fuses, and cables), or any combination thereof. For example, power supply 102 may be a utility grid or other power source, control system 110 may correspond to an EV charger, and auxiliary system may correspond to an EV.

In some embodiments, user interface 106 includes a push button, a toggle switch, a knob, a display screen (e.g., a touch screen), a key fob, a key-lock combination, any other suitable system or component for receiving input from a user or providing output to a user, or any combination thereof. In some embodiments, user interface 106 includes a touchscreen on the dash of a vehicle, configured to receive input from the user, and provide a display to the user. In some embodiments, user interface 106 includes one or more buttons that are selectable by a user. For example, the one or more buttons may include a button coupled to a switch, a button on a touchpad, any other suitable button that may be used by a user to make a selection, or any combination thereof.

In some embodiments, sensor(s) 104 include one or more current sensors (e.g., corresponding to AC or DC power), voltage sensors, any other suitable sensors, or any combination thereof. For example, sensor(s) 104 may be used to measure current in one or more phases of a motor (e.g., a multiphase motor coupled to a bridge circuit or other suitable motor driver), utility grid (e.g., a three-phase system), any other suitable electrical system, or a combination thereof. In a further example, sensor(s) 104 may include sensor leads (e.g., to directly measure voltage), current transformers (e.g., current-loop-sensors), voltage dividers, any other suitable sensor type, or any combination thereof.

Power electronics system 120 may be configured to power an inverter, an electric motor (e.g., induction motor, switched reluctance motor, or any other suitable electric motor type). For example, power electronics system 120 may be controlled by control circuitry 112 (e.g., using PWM commands or other suitable control signals), and may include an EV charger, inverter, or other suitable component. For example, power electronics system 120 may be controlled by control circuitry 112 (e.g., using PWM commands or other suitable control signals), to control AC-DC conversion, current flow in each phase of the motor, voltage across each phase of the motor, or a combination thereof over time (e.g., using transistors, a bridge circuit, a variable frequency drive, or using any other suitable control hardware).

Auxiliary system 130 may include any suitable system controlled by, or otherwise in communication with, control system, and that may interface to sensors 104. For example, sensors 104 may be configured to sense one or more characteristics of auxiliary system 130, or any other suitable system, and transmit corresponding sensor signals to control system 110 (e.g., COMM I/O 116 or sensor interface 114 thereof). Control circuitry 112 may be configured to process the sensor signals (e.g., the collected data) in real-time, post-process stored data arising from the sensor signals, or both. In some embodiments, control circuitry 112 may implement a noise detection process and a signal reconstruction process based on the received data, and then control auxiliary system 130 based on the reconstructed data.

Process 150 illustrates an illustrative technique implemented by control circuitry 112. For example, instructions for the technique may be stored in memory 118. Control circuitry 112 may receive original sensor data by sampling at least one sensor signal (e.g., one signal, two signals, or otherwise a plurality of sensor signals). The received data may be preprocessed. Control circuitry 112 may perform noise detection using any suitable technique to identify noise features or otherwise data that is suspected of being noise-corrupted. Noise detection may include using any suitable criteria such as thresholds, bands, transforms, filters, operations on the sampled data, any other suitable information, or any combination or comparison thereof. If noise is not detected, control circuitry 112 does not apply signal reconstruction and uses (e.g., outputs, stores, uses in computation and control) the original sampled data. If noise is detected, control circuitry performs signal reconstruction to reconstruct one or more samples of the original sensor data. While noise is detected, control circuitry 112 performs signal reconstruction and outputs filtered data. To illustrate, noise detection may act as a logic switch to cause either the original sensor data or reconstructed data to be used (e.g., outputted, stored, or used in computation and control).

In an illustrative example, system 100 may correspond to an EV charger. Control system 110 and power electronics system 120 may be interfaced to an AC grid, and may be configured to deliver a controlled amount of AC current (e.g., charging current or power) to an EV coupled to the charger. To illustrate, sensors 104 may include phase current sensors (e.g., one phase, three phase, multiphase) that provide sensor signals to sensor interface 114, which may be used to control power transistors, inverters, bridge circuits, any other suitable components electrically coupled to an AC grid, or any combination thereof. For example, control circuitry 112 may monitor sensor signals received at sensor interface 114, and determine currents, voltages, phases, statistical values derived thereof, or otherwise calculated values thereof, based on the sensor signals. Control circuitry 112 may be configured to control power electronics system 120 using PWM signals or other suitable control signals, based on a control algorithm that takes as input or parameter measured values or calculated values arising from the sensor signals. For example, control circuitry 112 may use one or more current measurements (e.g., of grid currents in each phase) to perform feedback control in providing EV charging or otherwise electric power from an AC source.

FIG. 2 is a flowchart of illustrative process 200 for applying a digital noise filter, in accordance with some embodiments of the present disclosure. For example, process 200 may implemented as a switchable noise filter (SNF). Control system 110 of FIG. 1 may be configured to implement process 200, for example. Process 200 provides an implementation of the technique illustrated by process 150.

Step 202 includes the system receiving sensor information. In some embodiments, data from one or more sensors (e.g., sensors 104) may be received at a suitable interface (e.g., sensor interface 114) of the system. To illustrate, the received data (e.g., sampled from the sensor signal) may be referred to as original sensor data. In some embodiments, step 202 may include processing such as for example, filtering, sampling, amplifying, converting, shifting, or a combination thereof (e.g., applied to all samples), and the output of step 202 may be subject to the switchable noise filter (e.g., steps 204, 206, 208, and 210, wherein step 206 acts as a logic switch).

Step 204 includes the system detecting signal noise in the received data of step 202. In some embodiments, the system may apply, for example, a moving average determination with bands to detect noise in the received data. In the context of grid currents, the band may be 20 Amps or larger, for example. In some embodiments, the system may apply IMF with bands, which may more effectively track harmonics (e.g., and may use asymmetrical bands). In some embodiments, the system may apply a phase-shifted IMF with bands, using phase-locked loop (PLL) information to shift the IMF forward (e.g., two steps forward for a two-step delay). For example, the phase-shifted IMF with bands may be able to track harmonics and use symmetrical bands. In some embodiments, the system may apply a dual-phase-shifted IMF with small bands, using four steps forwards and IMF (e.g., with a two-step delay) to construct the band. For example, the dual-phase-shifted IMF with small bands may be able to track harmonics and include symmetrical bands (e.g., as small as 2 Amps in the grid current context).

Step 206 includes the system determining whether to apply a digital noise filter based on the detected noise of step 204. In some embodiments, control circuitry 112 may generate or otherwise determine an upper and lower threshold to define a band. Control circuitry 112 may determine the thresholds at each sample index (e.g., each time step), thus defining a band nominally centered about a nominal value (e.g., a filtered value, a median value, a mean value, or otherwise a value outputted). For example, control circuitry 112 may determine a nominal value such as a median by applying an IMF technique (e.g., optionally using a phase-locked loop, phase shift or angle advancement), generate an upper and lower threshold based on the nominal value (e.g., an upper threshold greater than the nominal value and a lower threshold less than the nominal value), and then determine whether the original sensor data (e.g., the sample corresponding to the index) is greater than the upper threshold or lesser than the lower threshold (e.g., is outside of the band, and thus noise is detected). Control circuitry 112 may determine the thresholds using a fixed addition or subtraction (e.g., plus or minus 20 Amps for a current signal), a proportional determination (e.g., 110% and 90% of the nominal value), any other suitable technique for generating the thresholds, or any combination thereof. The difference (D1) between the upper threshold and the nominal value and between the nominal value and the lower threshold (D2) may be the same (e.g., a symmetrical band), or may be different (e.g., D2 need not equal D1). Because noise will tend to cause an excursion in the sampled data, the band may allow sufficient excursions to be detected. In some embodiments, control circuitry 112 determines whether to apply the digital noise filter by identifying an original data value (e.g., or differences in data values), determining a nominal value corresponding to the original data value, determining one more thresholds, and then comparing the original data value to the nominal value and/or thresholds. If noise is not detected (e.g., the sensor data does not exceed a threshold), then control circuitry need not perform step 208 and the sensor data may be outputted at step 210 (e.g., no reconstruction occurs for that sample index). Accordingly, each sample of the outputted data may be the original sensor data or reconstructed data depending on the determination of step 206.

Step 208 includes the system generating a reconstructed signal. In some embodiments, the system takes as input the received data at step 202 and generates the reconstructed signal (e.g., replacement data) based on the original sensor data. In some embodiments, the system may generate the reconstructed signal by applying a result from step 204. For example, in some embodiments, the system may use the result of an IMF filter to remove noise, by replacing the original collected data with filtered data. In a further example, the system may apply the IMF result with an angle advancement to remove noise and mitigate time delay. In some embodiments, the system may use a three-point IMF result from one or more executions of step 204. In some embodiments, in the context of multiphase systems, the system may generate the reconstructed signal of one phase based on signals corresponding to the other phases. For example, for a three phase system, the control system may replace noisy data with the sum of the other two phases opposite sign (e.g., replacement for phase “A” is “−(B+C)” because A+B+C are ideally equal to zero). In some embodiments, the system may generate the reconstructed signal using a technique that is selected based on the noise. For example, in the context of a multi-phase system, the control system may determine one or more than one phase exhibits noise. In a further example, the reconstruction technique may depend on the magnitude of the noise, or other characteristic of the noise.

Step 210 includes the system outputting the reconstructed signal. In some embodiments, step 210 includes outputting filtered data. Step 210 may include storing data (e.g., in memory 118), using data in computation, using data for control (e.g., to provide control signals to power electronics system 120), providing data for further processing, or any combination thereof. For example, the output of process 200 may be used in real-time or near real-time as an input or parameter to a control algorithm. Control circuitry 112 may generate a control signal based on the output of the switchable noise filter of process 200, to control power electronics system 120 (e.g., to control current flow or other behavior). Noise present in the sensor signal may be propagated to the control algorithm if not filtered, which may lead to instabilities, over-currents, component damage, or other undesired results. Because control circuitry 112 may perform the control in real-time, and requires data (e.g., sensor signals for feedback control) to provide accurate and stable control, process 200 may be used to mitigate noise in the sensor signals without having to perform a reconstruction (e.g., filter or sample replacement) at each sample (e.g., if noise is not detected, no reconstruction need occur).

In an illustrative example, a system may use a magnitude bandpass filter to remove larger noise features at step 202 (e.g., along with any other suitable processing). In a further example, a system may use an IMF (e.g., at step 204 and/or 208) to address noise, although a potential for delay and instability arises. In some embodiments, the system may implement process 200, using a switchable noise filter (SNF) that may be applied or not depending any suitable criteria. For example, in some embodiments, the system separates the filter into a noise detection process (e.g., step 204) and a signal reconstruction process (e.g., steps 206, 208, 210, or a combination thereof). In some embodiments, for example, the system may apply an IMF process to detect noise, and then insert replacement data (e.g., “good data,” reconstructed data, or otherwise noise-free data) to substitute the data exhibiting noise features (e.g., noisy data or “bad data”). In an illustrative example, the system may use any suitable technique to detect noise and insert good data.

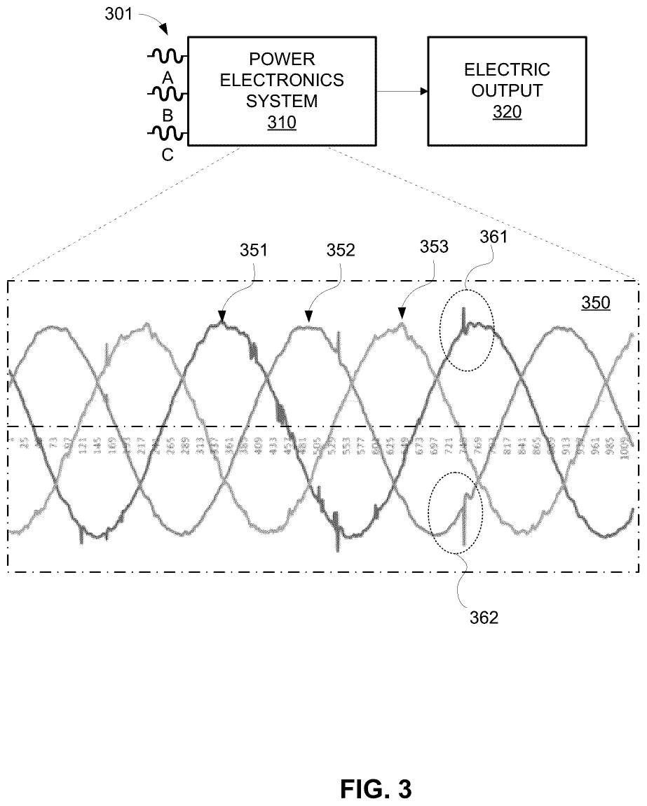

FIG. 3 is a block diagram of illustrative power electronics system 310 implementing a signal processing system for signals exhibiting noise (e.g., signals 351, 352, and 353), in accordance with some embodiments of the present disclosure. In some embodiments, power electronics system 310 may include, or be the same as, power electronics system 120, control system 110, and sensors 104. In some embodiments, power electronics system 310 may be separate from, but coupled to (e.g., communicatively coupled to), control system 110 and sensors 104. For example, signals 351, 352, and 353 may correspond to phases A, B, and C of a three-phase power source (e.g., a utility grid or service drop thereof). To illustrate, signals 351, 352, and 353 may correspond to grid currents of each respective phase as measured by respective current sensors (e.g., current shunts, toroidal current transformers, or any other suitable current sensor). For example, during operation, one or more signals 351, 352, and 353 may exhibit noise (e.g., indicated by feature 361), which may cause faults, distortion, or other artifacts if used for control or otherwise computation. For example, if power electronics system 310 implements current control for AC or DC charging (e.g., based on electric output 320), it may be affected by noise in grid current signals (e.g., signals 351-353).

In some embodiments, process 150 or 200 may be performed to apply a switchable digital noise filter. For example, the system may sample signals 351-353 (e.g., at a predetermined sampling frequency), and store the sampled data. The system may apply noise detection and identify feature 361, feature 362, or other suitable feature, for example, using any suitable technique. To illustrate, feature 361 may include a sampled value that exceeds a band or threshold, thus indicating sufficient noise is detected to cause the switchable filter to be applied. In some embodiments, the system may selectively reconstruct noisy data (e.g., corresponding to a feature such as feature 361 or 362), to avoid propagating the noise to subsequent calculations and control (e.g., of an electric output 320).

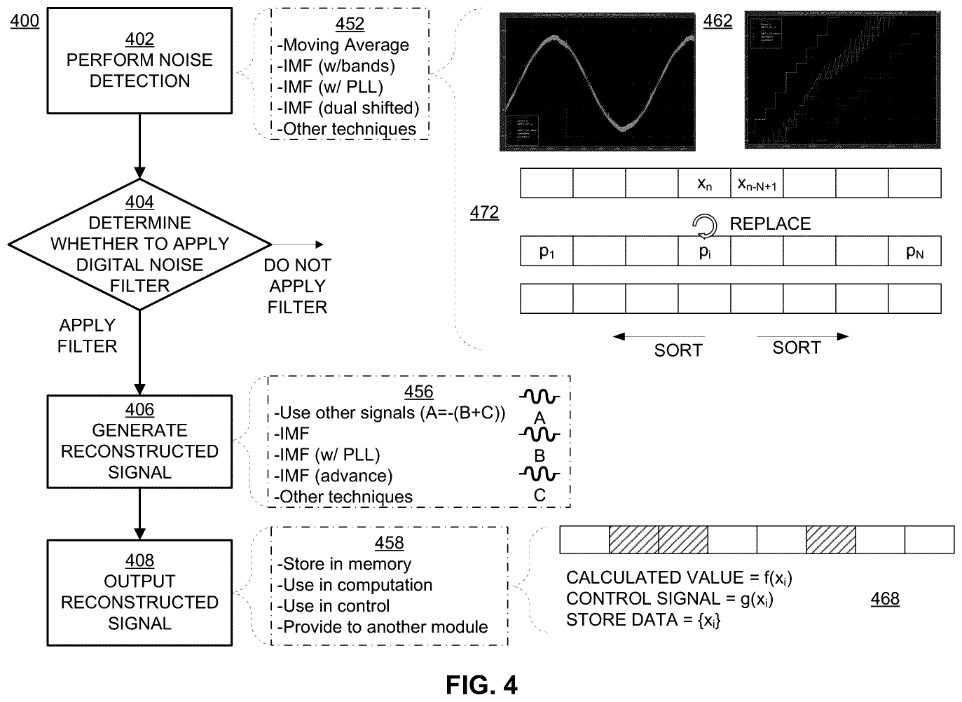

FIG. 4 is a flowchart of illustrative process 400 for implementing a switchable noise filter, in accordance with some embodiments of the present disclosure. For example, control system 110 (e.g., control circuitry 112 thereof) may be configured to implement process 400. In a further example, process 400 may illustrate an instance of process 150 or process 200. In a further example, memory 118 may include non-transitory computer-readable medium having instructions encoded thereon that when executed by control circuitry cause the control circuitry to perform process 400.

Step 402 includes the system performing noise detection for samples of a signal. In some embodiments, the system may perform noise detection for each sampled value. In some embodiments, the system may perform noise detection on a subset of sampled values (e.g., at a predetermined frequency, every M sample, in response to an indication noise is present). As illustrated in panel 452, one or more bands may be used for noise detection. For example, the system may apply an improved median filter (IMF) to the data, optionally using a phase locked loop (PLL) or dual-phase-shifting to correct for delay. In a further example, the system may apply a moving average calculation with upper and lower bands to identify noise values crossing the upper or lower bands. In a further example, panel 462 illustrates an underlying signal (e.g., generated from data using any suitable technique) and upper and lower bands (e.g., each equidistant from the underlying signal, as illustrated). Panel 472 illustrates some illustrative steps that may be used to perform noise detection. For example, data may be sorted in value (e.g., using a pointer p), the oldest sample may be replaced by the newest sample, and then the data may be resorted (e.g., although only a portion of the pointers need be updated depending on the new sample value compared to other values). In a further example, the median of the sorted data may be selected as the filtered value, used to generate upper and lower band thresholds (e.g., against which the original sample value may be compared during noise detection), or a combination thereof.

Step 404 includes the system determining whether to apply a digital noise filter. Step 404 may include the system determining whether a sampled value is outside of a range defined by upper and lower bands (e.g., one or more greater values and one or more lesser values at each sample index or time step), and determine to apply the filter if the sampled value is outside of the range. In some embodiments, steps 402 and 404 may be combined. For example, the system may determine to apply the noise filter based on noise detection as single processing step. In a further example, the system may output the sampled data without apply the switchable filter at step 404 (e.g., not apply the filter). In an illustrative example, process 400 may describe a switchable filter because step 404 functions as a logic switch to either apply the filter or not. Further, while the system may apply other filters, process 400 describes a switchable filter that is performed if noise is detected (e.g., stored data may include a combination of filtered and unfiltered data).

Step 406 includes the system generating a reconstructed signal. In some embodiments, the system generates the reconstructed signal from the underlying signal. For example, the system may generate filtered values based on the underlying signal (e.g., using an IMF or other suitable filter). In some embodiments, the system generates the reconstructed signal based on signals other than the underlying signal. For example, the system may use one or more other signals to generate the reconstructed signal at step 306. As illustrated in panel 456, the system may the reconstructed signal using any suitable technique such as IMF (e.g., with PLL, shifting, and/or bands), a set of signals, any other suitable technique, or any combination thereof. For example, the system may generate the reconstructed signal using any of the illustrative noise detection techniques of step 402. In some embodiments, the system may perform step 402 to detect noise using a filtering technique and, if noise is detected the system outputs the filtered value (e.g., steps 206 and 208 may be combined), while if noise is not detected the system may output the received data of step 202 (e.g., the original data is outputted and step 406 need not be performed).

Step 408 includes the system outputting the reconstructed signal of step 406. The system may, as illustrated in panel 458, store the data in memory (e.g., data from step 404 and 406 depending if the filter is applied), use the data in computation or control (e.g., as input to a control algorithm), provide the data to another module or device (e.g., remote memory storage, a network device, an application server, or any other suitable processing equipment), provide the data for any other suitable purpose, or any combination thereof. As illustrated in panel 468, stored data may include data from either leg of step 404 (e.g., filtered or unfiltered) depending on the prevalence of noise (e.g., shaded cells represent data from step 406 while unshaded cells represent data unfiltered data). As further illustrated in panel 468, the outputted data from step 408 may be used to determine one or more calculated values (e.g., using operator f), one or more control signals or values (e.g., using operator g), stored in a databased or other structure, or any combination thereof.

In some embodiments, step 402 of process 400 includes detecting, using control circuitry 112, noise in one or more of samples of a first signal that corresponds to a phase current of a multiphase system, at step. Step 404 may include determining, based on the noise, to apply a digital noise filter, and step 406 may include applying the digital noise filter. For example, step 406 may include generating a reconstructed signal based on two other signals corresponding to respective phase currents of the multiphase system, and outputting the reconstructed signal to replace the one or more samples. To illustrate, referencing FIG. 3, if feature 361 (e.g., a noise feature) is detected, the control circuitry may generate a reconstructed signal to replace samples of signal 351 by summing the corresponding samples of signals 352 and 353 and applying the opposite sign (e.g., reconstructed signal A′=−(B+C) because ideally A+B+C=0). Accordingly, the control circuitry may generate the reconstructed signal (A′) by combining the two other signals (e.g., B and C) to generate a combined signal (A′=−B−C). In some such embodiments, step 402 of process 400 includes receiving a first signal, a second signal, and a third signal that correspond to respective phase currents of a multi-phase system. In some such embodiments, control circuitry 112 generates the reconstructed signal by summing the other N−1 (e.g., N=3 for a three phase system) signals to generate a reference signal, and changing the sign of the reference signal to result in the reconstructed signal.

In some embodiments, control circuitry 112 may perform noise detection at step 402 by identifying an oldest sample in stored sorted data comprising N samples of the first signal, replacing the oldest sample with a new sample, reordering the sorted data to form updated sorted data, and identifying a median value among the updated sorted data. In some embodiments, control circuitry 112 may further perform noise detection at step 402 by determining phase information (e.g., using a phase-locked loop for cyclical phase currents) and shifting the median value based on the phase information to lessen a phase delay (e.g., a five-point IMF determination may incur a two-step delay if not shifted).

In some embodiments, control circuitry 112 may perform noise detection at step 402 by determining a mean based on N samples of the first signal, and comparing the one or more samples to the mean (e.g., applying a moving average to detect noise by determining a difference between a sample value and a computed mean value).

In some embodiments, control circuitry 112 may perform noise detection at step 402 by determining a median value based on the first signal, determining an upper band and a lower band based on the median value, and detecting the noise by determining whether the one or more samples are within a band defined by the upper band and the lower band (e.g., a sample value outside of the band may be identified as noise).

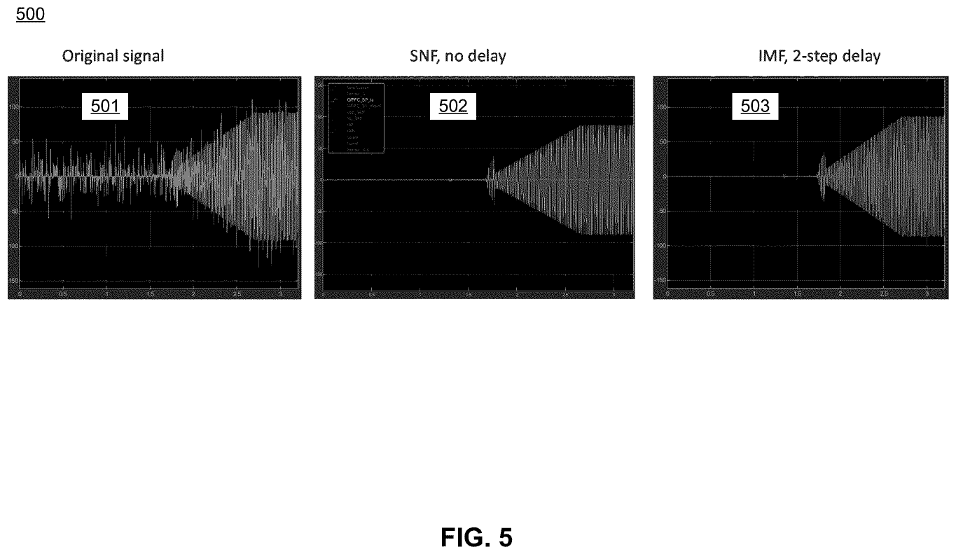

FIG. 5 shows a signal (e.g., signal 501) and resulting signals (e.g., signals 502 and 503) after applying noise mitigation techniques, in accordance with some embodiments of the present disclosure. Signal 501 corresponds to original sensor data corresponding to nominally zero values followed by a sinusoidal portion ramping/increasing in amplitude. Signal 502 corresponds to processed data determined using the switchable noise filter (SNF) of process 400, as applied to signal 501. Signal 503 corresponds to processed data using an IMF with a two-step delay, as applied to signal 501. As illustrated, the SNF of the present disclosure mitigates noise in signal 501, thus allowing accurate data determination and/or control based on sampled data exhibiting noise.

The foregoing is merely illustrative of the principles of this disclosure and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. A method comprising:
detecting, using control circuitry, noise in one or more of samples of a first signal that corresponds to a phase current of a multiphase system;
determining, based on the noise, to apply a digital noise filter; and
applying the digital noise filter by:
generating a reconstructed signal based on two other signals corresponding to respective phase currents of the multiphase system; and
outputting the reconstructed signal to replace the one or more samples.

2. The method of claim 1, wherein generating the reconstructed signal comprises combining the two other signals to generate a combined signal.

3. The method of claim 1, wherein:
the first signal, a second signal, and a third signal correspond to the respective phase currents of a three-phase system; and
generating the reconstructed signal comprises:
summing the second signal and the third signal to generate a reference signal; and
changing a sign of the reference signal to result in the reconstructed signal.

4. The method of claim 1, wherein detecting the noise comprises:
identifying an oldest sample in stored sorted data comprising N samples of the first signal;
replacing the oldest sample with a new sample;
reordering the sorted data to form updated sorted data; and
identifying a median value among the updated sorted data.

5. The method of claim 4, wherein detecting the noise further comprises:
determining phase information; and
shifting the median value based on the phase information to lessen a phase delay.

6. The method of claim 1, wherein detecting the noise comprises:
determining a mean based on N samples of the first signal; and
comparing the one or more samples to the mean.

7. The method of claim 1, wherein detecting the noise comprises:
determining a median value based on the first signal;
determining an upper band and a lower band based on the median value; and
detecting the noise by determining whether the one or more samples are within a band defined by the upper band and the lower band.

8. A system comprising:
a sensor system configured to generate a first signal that corresponds to a phase current of a multiphase system; and
control circuitry configured to:
sample the first signal;
detect noise in one or more of samples of the first signal,
determine, based on the noise, to apply a digital noise filter; and
apply the digital noise filter by:
generating a reconstructed signal based on two other signals corresponding to respective phase currents of the multiphase system; and
outputting the reconstructed signal to replace the one or more samples.

9. The system of claim 8, wherein the control circuitry is further configured to generate the reconstructed signal by combining the two other signals to generate a combined signal.

10. The system of claim 8, wherein:
the first signal, a second signal, and a third signal correspond to respective phase currents of a three-phase system; and
the control circuitry is further configured to generate the reconstructed signal by:
summing the second signal and the third signal to generate a reference signal; and
changing a sign of the reference signal to result in the reconstructed signal.

11. The system of claim 8, wherein the control circuitry is further configured to detect the noise by:
identifying an oldest sample in sorted data comprising N samples of the first signal;
replacing the oldest sample with a new sample;
reordering the sorted data to form updated sorted data; and
identifying a median value among the updated sorted data.

12. The system of claim 11, wherein the control circuitry is further configured to detect the noise further by:
determining phase information; and
shifting the median value based on the phase information to lessen a phase delay.

13. The system of claim 8, wherein the control circuitry is further configured to detect the noise by:
determining a mean based on N samples of the first signal; and
comparing the one or more samples to the mean.

14. The system of claim 8, wherein the control circuitry is further configured to detect the noise by:
determining a median value based on the first signal;
determining an upper band and a lower band based on the median value; and
detecting the noise by determining whether the one or more samples are within a band defined by the upper band and the lower band.

15. A non-transitory computer-readable medium having instructions encoded thereon that when executed by control circuitry cause the control circuitry to:
detect noise in one or more of samples of a first signal that corresponds to a phase current of a multiphase system;
determine, based on the noise, to apply a digital noise filter; and
apply the digital noise filter by:
generating a reconstructed signal based on two other signals corresponding to respective phase currents of the multiphase system; and
outputting the reconstructed signal to replace the one or more samples.

16. The non-transitory computer-readable medium of claim 15, wherein:
the first signal, a second signal, and a third signal correspond to respective phase currents of a three-phase system; and
the instructions comprise an instruction encoded thereon that when executed by control circuitry cause the control circuitry to generate the reconstructed signal by:
summing the second signal and the third signal to generate a reference signal; and
changing a sign of the reference signal to result in the reconstructed signal.

17. The non-transitory computer-readable medium of claim 15, wherein the instructions comprise an instruction encoded thereon that when executed by control circuitry cause the control circuitry to detect the noise by:
identifying an oldest sample in sorted data comprising N samples of the first signal;
replacing the oldest sample with a new sample;
reordering the sorted data to form updated sorted data; and
identifying a median value among the updated sorted data.

18. The non-transitory computer-readable medium of claim 17, wherein the instructions comprise an instruction encoded thereon that when executed by control circuitry cause the control circuitry to detect the noise further by:
determining phase information; and
shifting the median value based on the phase information to lessen a phase delay.

19. The non-transitory computer-readable medium of claim 15, wherein the instructions comprise an instruction encoded thereon that when executed by control circuitry cause the control circuitry to detect the noise by:
determining a mean based on N samples of the first signal; and
comparing the one or more samples to the mean.

20. The non-transitory computer-readable medium of claim 15, wherein the instructions comprise an instruction encoded thereon that when executed by control circuitry cause the control circuitry to detect the noise by:
determining a median value based on the first signal;
determining an upper band and a lower band based on the median value; and
detecting the noise by determining whether the one or more samples are within a band defined by the upper band and the lower band.
